(19) United States
(12) Patent Application Publication
(10) Pub. No.: US 2025/0055458 A1
(43) Pub. Date: Feb. 13, 2025

(54) CONTROL DEVICE INTERFACE ESPECIALLY FOR VENDING MACHINES AND DISPLAYS

(71) Applicant: CAREL INDUSTRIES S.p.A., Brugine (PD) (IT)

(72) Inventors: Gianpaolo ZILIO, Brugine (PD) (IT); Paolo MARAFIN, Brugine (PD) (IT)

(21) Appl. No.: 18/721,837

(22) PCT Filed: Dec. 16, 2022
(86) PCT No.: PCT/IB2022/062366

§ 371 Date: Jun. 19, 2024

(30) Foreign Application Priority Data
Dec. 23, 2021 (IT) 102021000032510

(51) Int. Cl. H03K 17/96

(52) U.S. Cl. CPC H03K 17/96; H03K 2217/96015; H03K 2217/96046; H03K 2217/960785

(57) ABSTRACT

Interface (10) for a control device having a front face (11) and a rear face (12) and comprising a plurality of layers grouped together in a covering assembly (13) and a tactile assembly (14) which extend between the front face (11) and the rear face (12); the covering assembly (13) comprises, in sequence: —a protective layer (15) having a front face (11); —a masking layer (16) which covers, directly or indirectly, a second face of the protective layer (15). The said tactile assembly (14) comprises—an operative layer (17) having sensitive pads (19) which are touch-responsive and permeable to light and transparent: —a matrix layer (21), which is opaque and provided with shaped portions (23) which are permeable to light or transparent or perforated and are aligned with the sensitive pads (19). The shaped portions (23) are configured to form markings (B) able to generate visible luminous symbols following backlighting of the interface (10). The sensitive pads (19) include tracks (18) which are discontinuous and distributed. The masking layer (16) has a light permeability such that the markings (B) are not visible through said masking layer (16) when said front face (11) is illuminated by a light radiation which results in a luminance not exceeding 4000 lx and the interface (10) is not backlit.

The present invention relates to an interface for an electronic control device, especially for refrigeration equipment such as vending machines, bottle coolers and refrigerated counters.

In particular, the interface according to the present invention allows an improved appearance to be obtained compared to traditional interfaces, as well as allowing integration of the interface in a decorative panel of a vending machine or display unit.

The interface in question is especially intended for controllers of refrigerated vending machines or display units, namely those comprising an internal housing refrigerated by a refrigerating machine controlled by the controller.

A particularly advantageous embodiment of the interface according to the invention allows the interface to be made invisible from the outside of the vending machine or display unit when the latter is inactive.

Nowadays, electronic control devices comprising a 7-segment display designed to form numerical symbols or stylized letters are known.

A 7-segment display consists of an integrated device which comprises a PCB having, fixed thereon, LEDs covered by a screen provided with seven segments, which are arranged in a figure of 8 and are translucent so that when each LED is switched on a segment lights up.

A touch-sensitive interface is fixed above the 7-segment display.

This comprises an interface screen provided with control symbols and a circuit which is fixed underneath the screen and has touch-sensitive components arranged opposite the control symbols.

In general, the touch-sensitive components are formed by a silver layer (conductive ink consisting of transparent silver (Ag)) which, owing its light permeability, allows the viewing from the outside of the backlit control symbols. This solution, however, is particularly sensitive to wear and fatigue during the working life of the product; in fact, the silver layer, in order to ensure suitable light-permeability (the transparent inks are a mixture of Ag and transparent organic resins which are sensitive to UV rays and therefore deteriorate over time owing to the exposure to UV rays), must have thicknesses which are such that the repeated mechanical stress due to compressive actuation tends cause deterioration thereof and results in a working life which is limited and, in any case, cannot be easily estimated a priori.

The interface screen is formed by two layers, an outer transparent layer and a finishing layer which is silkscreen-printed on the inner face of the outer layer so as to form a frame which surrounds the alphanumeric screen of the 7-segment display and which has the control symbols.

The customization of this traditional device may relate to the colour of the 7-segment display and/or the graphics of the interface screen.

In fact, special colours may be required for backlighting the colour and/or graphics display with personalized colours or style of the control symbols. Therefore, in order to ensure the availability of such customization, it is required to provide 7-segment displays with different colours and it may be necessary to commission from the interface screen supplier a multitude of customized silkscreen printed screens, to the detriment of the production economy in particular in the case of small batches.

Furthermore, traditional interfaces have the drawback that, when the interface is switched off or inactive, the sectors of the 7-segment display and/or any control icons, which would be backlit when in operation, are still visible.

This aspect is considered to be detrimental for the appearance of the controller. Italian patent number 102019000023187 discloses a solution which is greatly improved compared to the prior art described above.

In particular, this patent suggests a solution for realizing the touch-sensitive components integrally with the control symbols by means of selective deposition of a conductive layer which is shaped to form the control symbols and at the same time is touch-sensitive.

In fact, this document teaches the formation of an operative layer with electronic tracks which define an electrical circuit comprising sensitive pads, namely touch-responsive pads, and connection contacts which are designed to connect the electronic circuit to connectors of an electronic controller with which the interface is intended to be assembled.

The operative layer may consist of conductive ink which may for example consist in providing silver powder which is finely dispersed in a matrix of thermoplastic resin so as to be conductive.

In this way, the provision of the operative layer according to the patent Ser. No. 10/201,9000023187 allows the formation, in a single selective deposition operation, for example by means of silkscreen printing, of sensitive pads which form the operating symbols as well as being touch-sensitive.

This solution, while being very favourably viewed, is open to improvement.

In fact, it is per se known that, once the interface has been formed, it must be calibrated so that the signals can be derived from actuation of the interface opposite each control symbol and these signals must be able to be correctly read by the control software.

However, depending on the size of each control symbol and its form, understood as being the ratio and distribution of conductive material present and correspondingly absent for the desired graphics, the electrical conductivity of the corresponding sensitive pad of the operative layer may be non-uniform such that interfaces with different symbols must undergo special calibration. Therefore, the aim in the present document is to propose a solution which provides a further improvement compared to the solution disclosed in 102019000023187, in the name of the same Applicant, allowing a high quality production of interfaces, in the sense of uniform standardization of calibration thereof, irrespective and regardless of the graphics of the specially manufactured symbols associated with the production batch specifically requested by a customer or depending on the final destination.

The problem underlying the present invention is to simplify the production of interfaces of electronic control devices.

The task of the present invention is therefore to propose solutions to this problem by providing an interface for an electronic control device which allows simpler and more cost-effective customization compared to the traditional interfaces.

A further object of the invention is to provide an interface for an electronic control device which allows an improved appearance of the control device even when the interface is inactive.

Another task of the present invention is to provide an interface for a control device which is able to be integrated in an aesthetically attractive manner in the vending machine or display unit which incorporates the control device, even when the interface is inactive.

A further task of the present invention is to ensure a substantial uniformity in the reactivity of the sensitive pads of the interface, avoiding the need for specific calibration of interfaces with graphics which vary, namely have different symbols or sizes.

This task, as well as these and other objects which will become clearer below, are achieved by an interface for a control device according to the attached claim 1.

Detailed characteristic features of an interface for a control device, according to the invention, are contained in the dependent claims.

Further characteristic features and advantages will emerge more clearly form the description of a preferred, but non-exclusive embodiment of an interface for a control device according to the invention, shown by way of a non-limiting example in the attached sets of drawings in which:

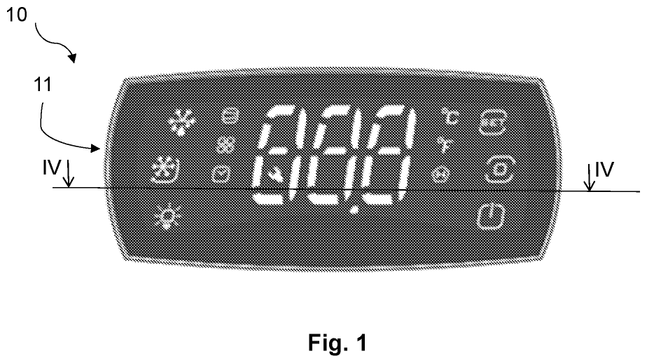

FIG. 1 shows a top plan view of an interface according to the present invention;

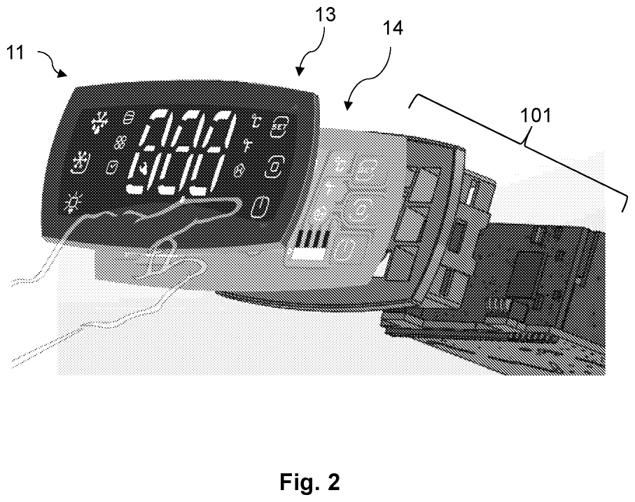

FIG. 2 shows an axonometric front view of the interface according to FIG. 1, with parts separated;

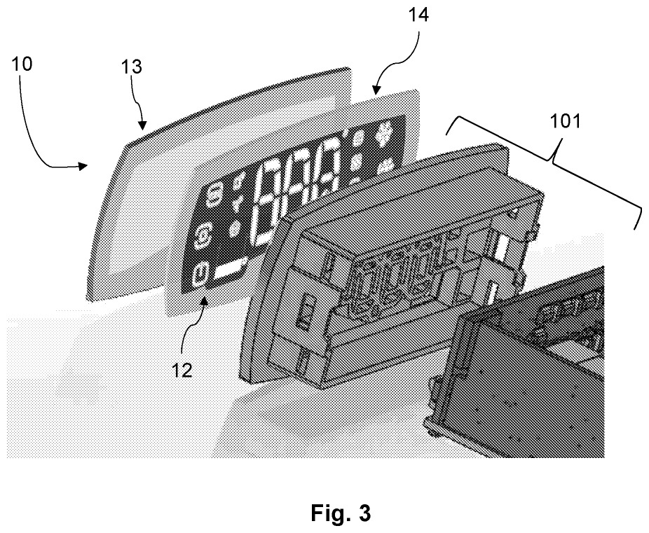

FIG. 3 shows an axonometric rear view of the interface according to FIG. 1, with parts separated;

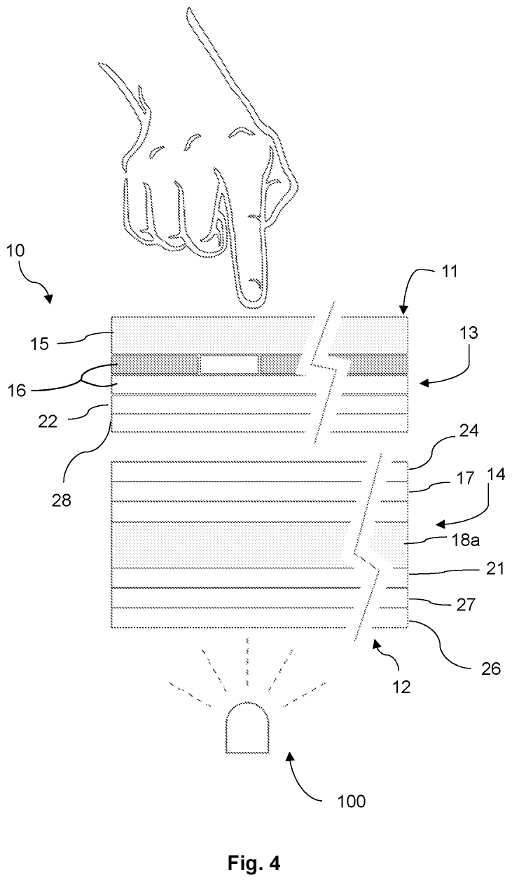

FIG. 4 shows a cross-section through an interface for a control device, according to the present invention, along the plane IV-IV of FIG. 1;

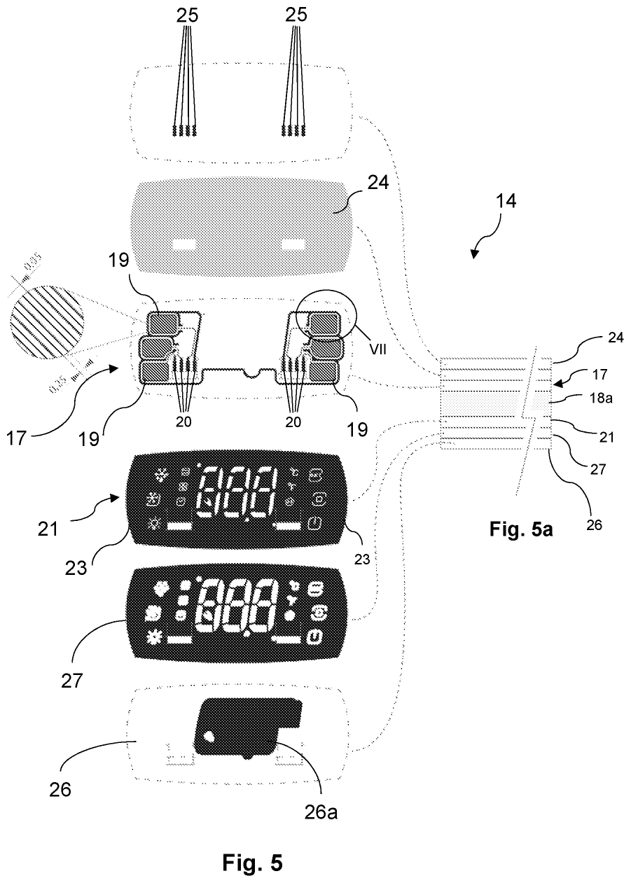

FIG. 5 shows a tactile assembly of an interface for a control device according to the present invention, with parts separated;

FIG. 5a shows a cross-section through the tactile assembly according to Figure, showing the respective stratification;

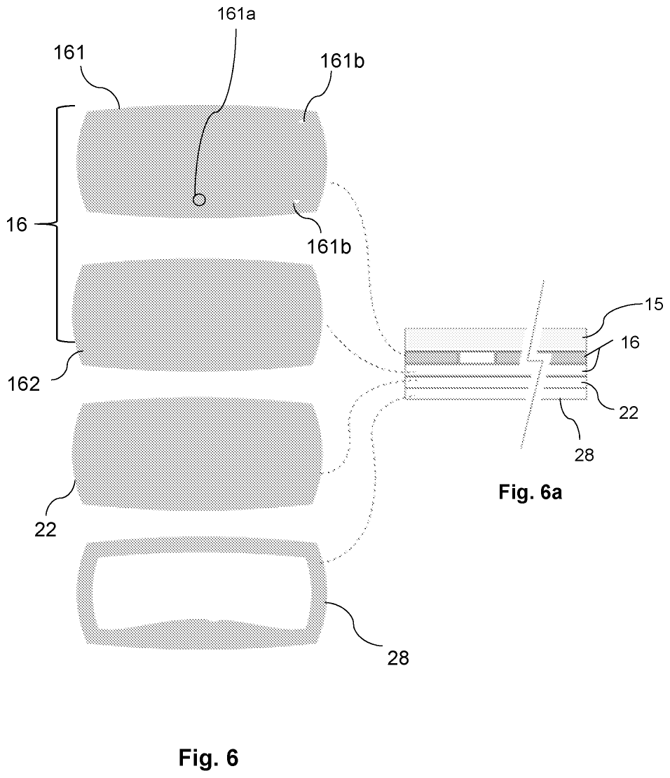

FIG. 6 shows a covering assembly of the interface according to FIG. 4 for a control device according to the present invention;

FIG. 6a shows a cross-section through the covering assembly according to FIG. 6, showing the respective stratification;

FIG. 7 shows an enlarged detail VII of FIG. 5;

FIG. 8 shows a cross-sectional view along the line VIII-VIII of FIG. 7;

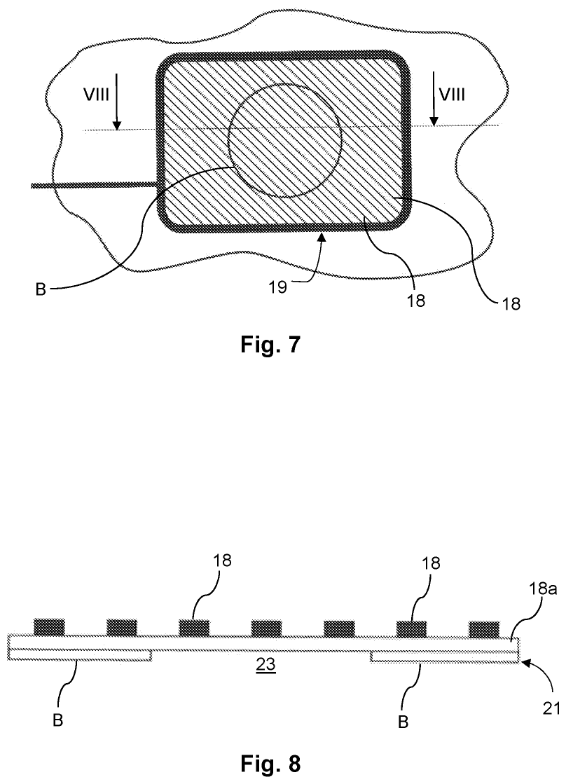

FIG. 9 shows a detail of a sensitive pad of an interface according to an embodiment of the present invention;

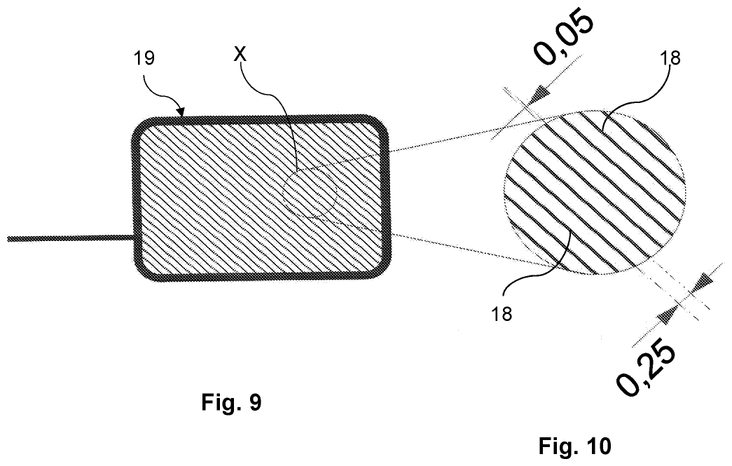

FIG. 10 shows an enlarged detail X of FIG. 9;

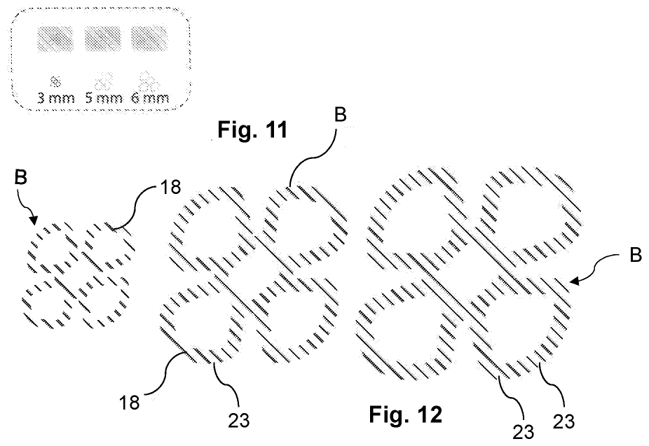

FIG. 11 shows in schematic form a series of icons in the format with increasingly larger dimensions provided according to the present disclosure;

FIG. 12 shows in schematic form, on a larger scale, a plurality of matrix layers and conductive tracks each corresponding to a respective icon from among the icons shown in FIG. 11.

With particular reference to the said figures, 10 denotes overall an interface for a control device.

The interface 10 may extend mainly in one plane and comprise, within its thickness, namely in a direction orthogonal to said plane, a plurality of layers. The interface 10 may have a front face 11 and a rear face 12, the plurality of layers extending between the front face 11 and the rear face 12 across the thickness.

In particular, the plurality of layers comprises: a covering assembly 13 and a tactile assembly 14. In other words, the layers of the plurality of layers are grouped together in a covering assembly 13 and a tactile assembly 14 which extend, within the thickness, between the front face 11 and the rear face 12.

The covering assembly 13 and the tactile assembly 14 may form two single articles, namely two articles which can be handled individually and fixed to each other during assembly of the interface 10 for example by means of an adhesive film, which may be provided with a removable liner for exposing it during joining of the covering assembly 13 together with the tactile assembly 14.

As is described more fully below, the covering assembly 13 and the tactile assembly 14 may be formed by silkscreen or offset printing one layer on top of the other, between the layers which make them up, where necessary starting from a support layer which will be described more fully below for each assembly.

The rear face 12 of the interface 10 can be fixed to a lighting device, generally indicated by the number 100 (FIG. 4), so that, when the latter emits a light radiation, said light radiation passes through the interface 10 from the rear face 12 to the front face 11.

An operative assembly 101—shown generally in FIGS. 2 and 3—which includes the lighting device 100, control electronics of the known type (not visible) and corresponding box-shaped support bodies, is associated with the rear face 12 of the interface 10. Since this operative assembly 101 is known it is not described below.

In detail, the covering assembly 13 comprise, in sequence, from the front face 11, at least:
a protective layer 15, having a first face which defines the front face 11; the protective layer 15 may form the aforementioned support layer of the covering assembly;
a masking layer 16 which covers, directly or indirectly, a second face of the protective layer 15.

The masking layer 16 may then be applied, for example by means of silkscreen or offset printing onto the protective layer 15 or onto a further layer which in turn is applied onto the protective layer 15 or onto another layer applied onto it. The protective layer 15 is for example made of transparent polycarbonate. The tactile assembly 14 comprises at least:
an operative layer 17 which has electronic tracks 18 defining an electrical circuit comprising sensitive pads 19, which are touch-responsive, and connection contacts 20 designed to connect the electronic circuit to connectors of an electronic controller with which the interface 10 is intended to be assembled;
a matrix layer 21 which is opaque and provided with shaped portions 23 which are permeable to light or transparent. The shaped portions 23 are aligned with, or associated in the region of, the sensitive pads 19, along the thickness of the interface 10.

According to a preferred aspect of the invention, the matrix layer 21 is separate or can be separated from the operative layer, as explained more clearly below.

The shaped portions 23 are configured to form markings B. In other words, the term “shaped portions” is understood as meaning zones of the matrix layer 21 which allow the passage of light and which, overall, define the markings (B) which must be visible on the front side 11. In other words, the shaped portions 23 are configured to form markings (B) able to generate visible luminous symbols following backlighting of said interface 10.

The sensitive pads 19 are permeable to light or transparent so as to allow the formation through them, of the aforementioned luminous symbols which are visible to an operator standing in front of the front face 11 of the interface 10.

The protective layer 15 of the covering assembly 13 is configured to transmit a touch-generated pressure so as to allow actuation of the sensitive pads 19 through it.

At least one of the covering assembly 13 and the tactile assembly 14 comprises a diffuser layer 22 which is configured to homogenize a light radiation passing through it.

In particular, the diffuser layer 22 of the covering assembly 13, where relevant, may extend, in plan view, over the entire shape of the protective layer 16 in order to diffuse transversely with respect to the thickness of the interface 10 a backlighting radiation, namely a radiation which is emitted from the rear face 12 of the interface 10 towards the front face 11.

The diffuser layer 22 of the covering assembly 13, where relevant, may cover completely or partially the masking layer 16, towards the rear face 12.

In particular, the diffuser layer 22 of the covering assembly 13, where relevant, may be applied by means of silkscreen or offset printing onto the masking layer 16 which may have been applied onto the protective layer 15 for example by means of silkscreen printing or offset printing.

In general, the diffuser layer 22 may consist of a glossy ink with a gloss of between 70 Gloss Units and 90 Gloss Units, at 60°, and may be made with the ink commercially known as Mara® Star SR produced by the company Marabu GmbH & Co. KG, as available on the date of filing the present application.

The masking layer 16 is placed, with respect to the thickness, between the front face 11 and the matrix layer 21 and has a light permeability such that the markings B are not visible through the masking layer 16 when the front face 11 is illuminated by a light radiation resulting in a luminance not exceeding 4000 lx and the interface 10 is not illuminated through the rear face 12.

The light permeability of the masking layer 16 is such that said markings B are visible through the masking layer 16 when the interface 10 is illuminated through the rear face 12 by a light source with a luminous intensity of not less than 45 mcd for example by LEDs emitting red light and powered at 5 mA and preferably with a luminous intensity of between 45 and 112.5 mcd, for example by red light LEDs powered at 5 mA, or between 280 and 630 mcd for example by white light LEDs powered at 5 mA.

In other words, the masking layer 16 has a light permeability such that the markings B are invisible, when viewing the front face 11 of the interface 10 under normal ambient lighting conditions, if the interface 10 is not backlit, namely illuminated through its rear face 12.

According to one aspect of the present disclosure, the sensitive pads 19 and/or said operative layer 17 are made by means of a substantially uniform distribution of conductive tracks 18 which form a graphic pattern forming a conductive matrix which is transparent and the electrical conductivity of which is substantially the same at each of said sensitive pads 19 or in groups thereof.

In other words, the sensitive pads 19 and/or said operative layer 17 include discontinuous conductive tracks 18, in which an empty zone, without conductive track 18, alternates with a conductive track 18.

More particularly, preferably the graphic pattern comprises a sequence of tracks 18 made of conductive material alternating with a plurality of portions free from said conductive material so as to allow the passage of light through them. Consequently, the graphic marking B may be visible through the tracks 18, without creating, however, any interdependence in terms of shape and size between the graphical marking B and the said tracks 18.

The present disclosure is therefore based on the recognition of having separated the tracks from the graphic marking B of the matrix 21. Consequently, as mentioned above, the matrix layer may be independent of the operative layer 17 and vice versa.

The operative layer 17 may therefore be associated with a plurality of matrix layers 21 which are each different and have the desired interface symbols. A kit is therefore obtained in which an assortment of matrices 21 which are different from each other may be associated with the same operative layer so that it is possible to create multiple arrangements of markings (B) and graphics.

Preferably, each of said tracks follows a predefined trajectory in which the trajectories of said tracks are preferably parallel. This allows the tracks 18 to be positioned above the underlying marking B and at the same to interfere as little as possible with the underlying marking B.

Even more preferably, in order to be perceivable as little as possible said trajectories are rectilinear.

The choice of trajectory, thickness and thickness of the tracks 18 depends on the final aesthetic effect which is to be obtained.

Owing to the geometry of the parts described above it may be understood that the interface 10 has a reference direction which, when the interface is in use, is vertical, horizontal or parallel or perpendicular to a support plane for a user or for an apparatus which incorporates said interface 10. The aforementioned trajectories have a main direction of development which intersects said reference direction so as to form an angle substantially of between 10° and 80°. Even more preferably, said interface has a main direction of development of said trajectories which is rectilinear or curvilinear, and a transverse direction which is substantially perpendicular to said main direction of development. More particularly, along said transverse direction, the tracks and the free portions each have a given thickness extension; the thickness extensions of said tracks are preferably all substantially the same and the thickness extensions of said free portions are all substantially the same.

This allows the sensitive pads 19 to be adapted to the form of the underlying graphics in a simplified manner.

For example, as shown in FIG. 5 or FIG. 10, a thickness extension is equal to 0.05 mm and the interaxial distance between each track is equal to 0.25 mm. Preferably, the conductive material of the tracks 18 comprises a conductive ink which comprises a silver powder finely dispersed in a thermoplastic resin matrix.

The tracks 18, or conductive paths, are arranged on a support layer 18a, for example made of polyester.

Consequently, when increasing the graphical markings or their appearance, the tracks may be left intact, as shown in the comparisons of FIGS. 11 and 12. An independence of the matrix layer 21 with respect to the operative layer 17 is therefore obtained. The operative layer 17 may also have a minimum thickness. With regard to the remaining parts of the interface 10 the following observations may be made.

The masking layer 16 may comprise a solvent-based ink layer or consists of said ink.

Moreover, in general, the masking layer 16 may be formed by means of deposition of said ink, by silkscreen or offset printing, on a further layer of said further layers of the plurality of layers.

Said ink may be deposited on the protective layer 15 which may be made of polycarbonate and extend, in plan view, over the whole shape of the interface 10.

In particular, the product known commercially as Mara® Panel MPA produced by Marabu GmbH & Co. KG, as commercially available on the date of filing of this application, may be used as the ink for making said masking layer 16.

In order to electrically insulate the operative layer 17, the ink of the masking layer 16 may be electrically insulating and may have an electrical resistance of more than 1012 Ohm.

The masking layer 16 may comprise in sequence, towards the rear face 12:
a chromatic masking layer 161 designed to comprise portions with different colours, for example aimed at forming a logo 161a or other commercial and/or functional symbols 161b, distributed in a matrix complementing them with respect to the plan-view shape of the protective layer 15;
a diffuser masking layer 162.

The chromatic masking layer 161 may be coloured overall so as to impart to the graphical markings (B) which are visible from the front face a predefined colour when they are backlit.

The diffuser masking layer 162 has the function of homogenizing a light radiation so that the markings B appear uniform when illuminated through the rear face 12 of the interface 10.

The protective layer 15 may comprise or consist of, as already mentioned, a transparent layer of polymethyl methacrylate or polycarbonate.

Moreover, the protective layer 15 has a transparency of not less than 80%, as defined in the DIN EN ISO 13468-3 test, and preferably has a thickness of between 0.75 mm and 15 mm and preferably equal to 1 mm.

This gives the covering assembly 13 an adequate structural consistency which allows easy and safe handling thereof during assembly of the interface 10 and, at the same time, adequate transparency and smaller overall dimensions.

The tactile assembly 14 may also comprise a support layer 26 on which the further layers included in tactile assembly 14 may be applied, either directly or indirectly.

The support layer 26 may comprise a polyester film, which can be stabilized for high temperatures, that is, for example, have a percentage shrinkage of less than 0.2% at 170° C., and may have a thickness of between 0.1 mm and 0.125 mm.

In order to electrically insulate and at the same time protect the operative layer 17, the tactile assembly 14 may comprise an electrically insulating coating layer 24, which coats, towards the front face 11, the operative layer 17, except for the connection contacts 20.

The coating layer 24 may be made of dielectric material and may have a dielectric strength of at least 500 V-AC for a thickness of 30 μm, or at least 2400 V-AC for a thickness of 25 μm, determined using the ASTM D149-81 Method A. The coating layer 24 may be made by silkscreen or offset printing an ink onto the operative layer 17, for example said ink may consist of the product commercially known as Electrodag® ML 25208 produced by Acheson Colloiden B.V. or the product D 150 El produced by Chi et S.P.A, as commercially available at the date of filing of this application.

In order to guarantee electrical conduction and at the same time protection of the connection contacts 20, the tactile assembly 14 may comprise covering elements 25, comprising graphite which may be included in a matrix of polymeric material which may be a thermoplastic resin.

The covering elements 25 may cover the connection contacts 20 left uncovered by the coating layer 24 and may complement the latter.

The covering elements 25 may be made by means of silkscreen or offset printing, on the operative layer 17, before or after the application of the coating layer 24.

An ink which can be used to make the covering elements 25 may be the one commercially known as Electrodag® 965 SS produced by Acheson Colloiden B.V., as commercially available at the date of filing of this application.

The matrix layer 21 may also be electrically insulating and may be made of dielectric material and have a dielectric strength of at least 2400 V-AC for a thickness of 25 μm, determined using the ASTM D149-81 Method A.

As mentioned, the electronic tracks 18 of the operative layer 17 may consist of a conductive ink based on silver powder finely dispersed in a matrix which may be made of thermoplastic resin.

For example, this conductive ink based on silver powder can be selected from those commercially known as:
Electrodag® PF-410 produced by Acheson Industries (Europe) Ltd;
Ag515EI produced by Chimet SpA;
Electrodag® 725A-6S-54 produced by Acheson Colloids Company.

The diffuser layer (not shown in the drawings) of the tactile assembly, where present, may be shaped so as to consist of a plurality of shaped parts aligned with the markings B, along the thickness of the interface 10, so as to homogenize the light directed towards them from the rear face 12.

The sensitive pads 19 may be delimited and aligned with the markings B, in relation to the thickness of the interface 10.

The matrix layer 21 may consist of shaped portions 23, in an opaque ink having a lightfastness of between 7 and 9 according to the blue wool scale defined by the DIN standard 16525.

The interface 10, or rather the tactile assembly 14, may also comprise a light-limiting layer 27.

The light-limiting layer 27 may be integrated in the tactile assembly 14 and may comprise a shaped part 27a which is transparent and may be coloured and is configured to be aligned, in the direction of the thickness of the interface 10, selectively with some of the markings B, namely of the shaped portions 23 of the matrix layer 21.

The light-limiting layer 27 may be arranged between the matrix layer 21 and the rear face 12 of the interface 10.

The light-limiting layer 27 has a non-conductive black colour (except for the shaped parts 27a) so as to limit the transmission of light outside of the shaped parts 27a and optionally give the latter exclusively a predefined colour when they are backlit.

In other words, the light-limiting layer 27 may have a non-conductive black colour and strengthen the masking capacity on the part of the non-conductive layer, which is preferably made of non-conductive silver, of the matrix layer 21.

The light-limiting layer 27 is made by means of silkscreen or offset printing, for example onto a face of the support layer 26, where for example the matrix layer 21 is applied on the other face or may be applied onto a further layer, for example on a diffuser layer of the tactile assembly 14 where present.

The interface may also comprise a covering layer 28 which can be integrated into the covering assembly 13 and which can be shaped to form a frame extending along the perimeter of the plan-view shape of the interface 10 and which has the function of hiding the presence of an adhesive for fixing the interface 10 to a lighting device.

The covering layer 28 may also consist of an opaque ink with a lightfastness between 7 and 8 according to the blue wool scale defined by the DIN standard 16525.

The interface 10 may comprise a perimeter lip for ultrasonic projection welding to the lighting device, in which case the covering layer 28 is not necessary and need not be incorporated in the interface 10.

At least one of the operative layer 17, the coating layer 24, the covering elements 25, may be deposited by means of silkscreen or offset printing directly or indirectly onto one of the faces of the support layer 26.

At least one of the diffuser layer 22 of the tactile assembly 14, the chromatic layer 27 and the matrix layer 21 may be deposited by means of silkscreen or offset printing directly or indirectly, rather than on said first face, onto a second face of the protective layer 15, in order to avoid interactions between one or more of these layers with the operative layer 17, so as to preserve the technical functionality of the latter.

For example, the matrix layer 21 can be applied directly onto the support layer 26.

The invention thus devised may be subject to numerous modifications and variations, all of which fall within the scope of protection of the attached claims. Moreover, all the details may be replaced by other technically equivalent elements.

In practice the materials used as well as the associated forms and dimensions may be varied depending on the particular requirements and the state of the art. Where the constructional characteristics and the techniques mentioned in the following claims are followed by reference numbers or symbols, these reference numbers or symbols have been assigned with the sole purpose of facilitating understanding of the said claims and consequently they do not limit in any way the interpretation of each element which is identified, purely by way of example, by said markings B or reference numbers.

1. Interface (10) for control device having a front face (11) and a rear face (12) and comprising a plurality of layers grouped together in a covering assembly (13) and a tactile assembly (14) which extend between said front face (11) and said rear face (12); said rear face (12) being able to be fixed to a lighting device so that, when the latter emits light radiation, said light radiation crosses said interface (10) from said rear face (12) to said front face (11);
wherein said covering assembly (13) comprises, in sequence, from said front face (11):
a protective layer (15) having a first face defining said front face (11);
a masking layer (16) directly or indirectly covering a second face of said protective layer (15);
wherein said tactile assembly (14) comprises
an operative layer (17) having electronic tracks (18) defining an electrical circuit comprising sensitive pads (19), which are touch-responsive, and connection contacts (20); said sensitive pads (19) being permeable to light, transparent or perforated;
a matrix layer (21), which is opaque and provided with shaped portions (23) which are permeable to light or transparent or perforated and are aligned with, or associated in the region of, said sensitive pads (19), along said thickness;
wherein said shaped portions (23) are configured to form markings (B) able to generate visible luminous symbols following backlighting of said interface (10);
wherein said protective layer (15) is configured to transmit a touch-generated pressure so as to allow the actuation of said sensitive pads (19) through it;
wherein said covering assembly (13) and/or said tactile assembly (14) comprises:
a diffuser layer (22) configured to homogenize light radiation passing through it;
wherein said masking layer (16) has a light permeability so that said markings (B) are not visible through said masking layer (16) when said front face (11) is illuminated by light radiation which produces an illumination of not more than 4000 lx and said interface (10) is not illuminated through said rear face (12); said light permeability being such that said markings (B) are visible through said masking layer (16) when said interface (10) is illuminated through said rear face (12) by a light source having a luminous intensity of not less than 45 mcd, for example for LEDs emitting red light and powered at 5 mA, and preferably having a luminous intensity of between 45 and 112.5 mcd, for example for red light LEDs powered at 5 mA or between 280 and 630 mcd for example for white light LEDs powered at 5 mA;
wherein said sensitive pads (19) and/or said operative layer (17) are realized by the distribution of electronic tracks (18) forming a graphic pattern which forms a conductive matrix which is transparent and the electrical conductivity of which is substantially the same at each of said sensitive pads (19) or in groups thereof.

2. Interface (10) according to claim 1, wherein said graphic pattern comprises a sequence of tracks (18) of conductive material alternating with a plurality of portions free from said conductive material so as to allow the passage of light through them, said sequence of tracks (18) being placed on a support layer (18a).

3. Interface (10) according to one of the preceding claims, wherein each of said tracks follows a predefined trajectory wherein the trajectories of said tracks are preferably parallel.

4. Interface (10) according to claim 3, wherein said trajectories are parallel.

5. Interface (10) according to one of claims 3 and 4, wherein said trajectories are straight.

6. Interface (10) according to one of claims 4 and 5, wherein said interface (10) has a reference direction which, when the interface is in use, is vertical, horizontal or parallel or perpendicular to a support plane for a user or for an apparatus which incorporates said interface (10); said trajectories having a main direction of development which intersects said reference direction preferably so as to form an angle substantially of between 10° and 80°.

7. Interface (10) according to one of the preceding claims, wherein said interface has a main direction of development of said trajectories, which is rectilinear or curvilinear, and a transverse direction which is substantially perpendicular to said main direction of development;
wherein, along said transverse direction, each of said tracks and said free portions have a thickness extension; the thickness extensions of said tracks being all substantially the same and the thickness extensions of said free portions being all substantially the same.

8. Interface (10) according to claim 2 and one of the preceding claims, wherein said conductive material comprises a conductive ink which comprises a silver powder finely dispersed in a thermoplastic resin matrix.

9. Interface (10) according to any one of the preceding claims, wherein said masking layer (16) comprises or consists of a solvent-based ink layer.

10. Interface (10) according to the preceding claim, wherein said ink is deposited by silkscreen printing or offset printing on one of the further layers of said plurality of layers.

11. Interface (10) according to the preceding claim, wherein said ink is deposited on said protective layer (15), which may be made of polycarbonate.

12. Interface (10) according to one of the preceding claims 9 to 11, wherein said ink is electrically insulating and may have an electrical resistance greater than 1012 Ohm.

13. Interface (10) according to one of the preceding claims, wherein said masking layer (16) comprises, in sequence, towards said rear face (12):
a chromatic masking layer (161) designed to include differently coloured portions;
a diffuser masking layer (162).

14. Interface (10) according to one of the preceding claims, wherein said diffuser layer (22) consists of a glossy ink having a gloss of between 70 Gloss Units and 90 Gloss Units, at 60°.

15. Interface (10) according to one of the preceding claims, wherein said diffuser layer (22) covers said masking layer (16), towards said rear face (12).

16. Interface (10) according to one of the preceding claims, wherein said tactile assembly (14) comprises an electrically insulating coating layer (24) which coats, towards said front face (11), said operative layer (17) except for said connection contacts (20); said coating layer (24) which may be made of dielectric material and may have a dielectric strength of at least 500 V-AC for a thickness of 30 μm, or of at least 2400 V-AC for a thickness of 25 μm, determined according to the ASTM D149-81 Method A.

17. Interface (10) according to one of the preceding claims, wherein said tactile assembly (14) comprises covering elements (25), comprising graphite optionally included in a matrix of polymeric material which may be a thermoplastic resin; said covering elements (25) cover said connection contacts (20) left uncovered by said coating layer (24) and complement the latter.

18. Interface (10) according to one of the preceding claims, wherein said matrix layer (21) is electrically insulating, may be made of dielectric material and may have a dielectric strength of at least 2400 V-AC for a thickness of 25 μm, determined according to the ASTM D149-81 Method A.

19. Interface (10) according to one of the preceding claims, wherein the electronic tracks (18) of said operative layer (17) consist of a silver based conductive ink with silver powder finely dispersed in a matrix which may be made of thermoplastic resin.

20. Interface (10) according to one of the preceding claims, wherein said protective layer (15) comprises or consists of a layer of polymethyl methacrylate or polycarbonate which is transparent; said protective layer (15) has a transparency of not less than 80%, as defined in the DIN EN ISO 13468-3 test, and preferably has a thickness of between 0.75 mm and 15 mm and preferably equal to 1 mm.

21. Interface (10) according to one of the preceding claims, comprising a light-limiting layer (27) having shapes corresponding to the shaped portions (23) of the matrix layer and associated with the matrix layer (21) on one side facing the rear face (12) and designed to limit the passage of light that passes through it, directed towards said front face (11) and/or to strengthen a masking capacity of said matrix layer (21).

22. Interface (10) according to one of the preceding claims, wherein said matrix layer (21) consists, except in said shaped portions (23), of an opaque ink having a lightfastness of between 7 and 8 according to the blue wool scale defined by the DIN 16525 standard.

23. Interface (10) according to one of the preceding claims, wherein the distribution of said tracks (18) is substantially homogeneous and/or wherein said tracks (18) have a shape independent of the shape of said shaped portions (23) of said matrix layer (21) and/or wherein said operative layer (17) is independent of said matrix layer (21).

24. Kit including an interface (10) according to one of the preceding claims and an assortment of matrices (21) which are different from each other.
